(19) United States
(12) Patent Application Publication
(10) Pub. No.: US 2022/0320828 A1
(43) Pub. Date: Oct. 6, 2022

(54) METHOD FOR PRODUCING LAMINATE, LAMINATE, LIGHT-EMITTING DEVICE AND LASER DEVICE

(71) Applicants: KYUSHU UNIVERSITY, NATIONAL UNIVERSITY CORPORATION, Fukuoka-shi, Fukuoka (JP); KOALA Tech Inc., Fukuoka-shi, Fukuoka (JP)

(72) Inventors: Matthew Ryan LEYDEN, Fukuoka-shi, Fukuoka (JP); Toshinori MATSUSHIMA, Fukuoka-shi, Fukuoka (JP); Chihaya ADACHI, Fukuoka-shi, Fukuoka (JP)

(21) Appl. No.: 17/616,239

(22) PCT Filed: Jun. 5, 2020
(86) PCT No.: PCT/JP2020/022325

§ 371 Date: Dec. 3, 2021

(30) Foreign Application Priority Data
Jun. 5, 2019 (JP) 2019-105071

(51) Int. Cl. H01S 5/12; C09K 11/06; C08J 5/18

(52) U.S. Cl. CPC H01S 5/1231; C09K 11/06; C08J 5/18; C09K 2211/10; C08J 2367/02

(57) ABSTRACT

Disclosed is a method for producing a laminate of a resin film and a perovskite film, including compressing a preliminary product having a resin film, a perovskite film and an inorganic support in that order with heating, followed by separating the laminate of a resin film and a perovskite film from the inorganic support. According to the production method, a perovskite film having a fine indented pattern such as a diffraction grating structure can be produced in a simplified manner

### TECHNICAL FIELD

The present invention relates to a laminate useful as a light-emitting device such as a laser device, and to a method for producing the laminate.

### BACKGROUND ART

Perovskites are an emergent family of materials that demonstrate promise for low cost lasing applications. Perovskites have demonstrated performance that is notable for organic lasers, such as the demonstration of continuous wave operation at low temperature, and high stability under continued pulsed operation. Additionally the emission is tunable through the visible spectrum, demonstrating lasing the blue region with cesium lead chloride (425 nm), and well into the near infrared with formamidinium tin iodide (896 nm). The bandgap has been correlated with the pseudo lattice constant, and the tuning of the lattice constant and band gap is usually done by modifying the halide composition of the perovskite. However, not all wavelengths are easy to accessible as many compositions are not stable and will undergo phase segregation. Lasing has also been demonstrated using low-dimensional perovskite, and shows some potential for electrically driven lasing application. Perovskite materials are analogous to a solution processed gallium arsenide. Both are direct bandgap semiconductors, and require a carrier concentration around 1×10¹⁸ cm³ for lasing. Due to the low material cost and simple deposition procedure, perovskites may be promising for low cost lasing applications.

Distributed-feedback (DFB) gratings can be efficiently applied to thin film semiconductors lasers. In 2^{nd} order DFBs laser emission is normal to the surface and convenient for amorphous or polycrystalline films. The resonant mode of the cavity is defined by the following equation, m_{BraggλBragg}=2n_{eff}λ, where m_{Bragg} is the order, λ_{Bragg} is the PL wavelength, n_{eff} is the effective refractive index, and λ is the grating pitch. For relevant wavelengths the grating needs to be patterned with sub-micron pitch requiring expensive lithography. There have been a number of reports on grating replication for application in perovskite lasers. Some methods have focused on grating replication with UV-curable resin, followed by the application of a thin film of perovskite (see NPLs 1 and 2). Other processes pattern the perovskite film itself such as directly nano-imprinting the perovskite film (see NPL3), or a mask layer can be imprinted followed by argon ion sputtering to remove perovskite (see NPL 4). Analogous methods have been applied to fabrication of photonic crystal lasers (see NPLs 5 and 6). In many of these examples the perovskite precursor solution needs to be compatible with the substrate. For example, dimethylformamide (DMF) may dissolve the UV-resin used to reproduce gratings, and dimethyl sulfoxide (DMSO) will dissolve low cost flexible substrates like PET.

### CITATION LIST

### Non Patent Literature

[NPL 1] Appl. Phys. Lett. 109, 141106 (2016).

[NPL 2] Opt. Express, OE 24, 23677 (2016).

[NPL 3] Advanced Materials Technologies 3, 1700253 (2018).

[NPL 4] Advanced Materials Technologies 3, 1800212 (2018).

[NPL 5] Advanced Materials 29, 1605003 (2017).

[NPL 6] ACS Photonics 4, 2522 (2017).

### SUMMARY OF INVENTION

As described above, various methods have been proposed for forming a fine indented pattern such as a diffraction grating structure on a perovskite film. However, all those methods include complicated steps and require high production costs, especially including a step of bringing a resin substrate and a UV-curable resin into contact with a coating film for forming a perovskite film, and are therefore problematic in that solvent selection for the coating liquid therein is difficult, that is, the methods are impracticable. Given the situation and for the purpose of solving the problems in the conventional art, the present inventors made assiduous studies for providing a novel method capable of forming a perovskite film having a fine indented pattern such as a diffraction grating structure in a simplified process.

As a result of assiduous studies, the present inventors have found that, by forming a perovskite film on an inorganic support to be a master grating followed by laminating a resin film thereon and further followed by compression with heating, the surface profile of the inorganic support can be precisely transferred onto the perovskite film and simultaneously the resin film can be welded to the perovskite film to thereby readily give a laminate of a fine indented pattern-having perovskite film and a resin film, and have completed the present invention. On the basis of such findings, the present invention has been proposed here, and specifically has the following constitution.

[1] A method for producing a laminate of a resin film and a perovskite film, including compressing a preliminary product having a resin film, a perovskite film and an inorganic support in that order with heating, followed by separating the laminate of a resin film and a perovskite film from the inorganic support.

[2] The method for producing a laminate according to [1], wherein the preliminary product is sealed in a bag and then compressed with heating.

[3] The method for producing a laminate according to [2], wherein the compression is carried out under hydrostatic pressure.

[4] The method for producing a laminate according to any one of [1] to [3], wherein the preliminary product is pressed under 100 MPa or more.

[5] The method for producing a laminate according to any one of [1] to [4], wherein the heating is up to a temperature not lower than the glass transition temperature of the resin constituting the resin film and lower than the melting point thereof.

[6] The method for producing a laminate according to any one of [1] to [4], wherein the heating is up to a temperature not lower than 40° C. and lower than the glass transition temperature of the resin constituting the resin film.

[7] The method for producing a laminate according to any one of [1] to [6], wherein the inorganic support is a master grating and the perovskite film has a grating.

[8] The method for producing a laminate according to [7], wherein the perovskite film is formed by applying a perovskite film-forming coating liquid onto the surface of the grating-having inorganic support in a mode of spin coating.

[9] The method for producing a laminate according to any one of [1] to [8], wherein the resin film is a thermoplastic resin film.

[10] The method for producing a laminate according to [9], wherein the resin film is a polyethylene terephthalate film.

[11] The method for producing a laminate according to any one of [1] to [9], wherein the resin film is a fluororesin film.

[12] The method for producing a laminate according to [11], wherein the resin film is a polytetrafluoroethylene film.

[13] A laminate of a resin film and a perovskite film, wherein the resin film is welded to the perovskite film.

[14] The laminate according to [13], wherein the perovskite film has a grating on the surface opposite to the resin film side.

[15] The laminate according to [13] or [14], wherein the perovskite film contains a perovskite compound represented by the following general formula (4):

A³BX₃ (4)

wherein A³ represents an organic cation, B represents a divalent metal ion, X represents a halide ion, and three Xs may be the same as or different from each other.

[16] The laminate according to any one of [13] to [15], wherein the resin film is flexible.

[17] The laminate according to any one of [13] to [16], wherein the resin film is a thermoplastic resin film.

[18] The laminate according to [17], wherein the resin film is a polyethylene terephthalate film.

[19] The laminate according to any one of [13] to [17], wherein the resin film is a fluororesin film.

[20] The laminate according to [19], wherein the resin film is a polytetrafluoroethylene film.

[21] The laminate according to any one of [13] to [20] for light-emitting devices.

[22] The laminate according to any one of [13] to [20] for laser devices.

[23] A light-emitting device having the laminate of any one of [13] to [20].

[24] A laser device having the laminate of any one of [13] to [20].

[25] The laser device according to [24], which is a distributed-feedback laser device.

According to the production method for a laminate of a resin film and a perovskite film of the present invention, a laminate having a fine indented pattern such as a diffraction grating structure on a perovskite film can be produced in a simplified manner. The laminate of the present invention can be produced in a simplified manner, and therefore by applying the laminate to light-emitting devices such as laser devices, the production cost for the devices can be greatly reduced. Specifically, the laminate production method of the present invention exhibits the following advantageous effects. In this process there is no need to repeat the lithography process and it does not require a UV-curing resin to create the laser cavity as the cavity is made from the perovskite material itself. Additionally the film formation is largely independent of the final substrate, and there will be no concern about solvent compatibility. The film is formed on the master grating and transferred to the final substrate. The master grating can then be used again. This technique is potentially useful for optically pumped laser applications with organic gain material like perovskite.

### BRIEF DESCRIPTION OF DRAWINGS

FIGS. 1A-1E include schematic cross-sectional views of a production method for a laminate of the present invention. FIG. 1A shows an inorganic support having an indented pattern on the transfer surface thereof. FIG. 1B shows perovskite film formation. FIG. 1C shows resin film formation. FIG. 1D shows compression. FIG. 1E shows separation of the perovskite film from the inorganic support.

FIG. 2 includes schematic cross-sectional views of a hydrostatic pressing step for a preliminary product with heating.

FIG. 3 includes photographs of a laminate produced in Example 1.

FIG. 4 is a graph showing measurement results at a lasing threshold (14 μJ/cm²) of a laminate having a primary diffraction grating structure formed on a perovskite film among the laminates produced in Example 1.

FIG. 5 shows emission spectra measured at 16 μJ/cm² of laminates produced by varying the grating pitch of the perovskite film therein.

FIGS. 6A-6C include AFM photographs each showing a primary diffraction grating structure of a perovskite film. The resolutions of FIGS. 6A-6C increase in order.

FIG. 7 is an emission spectrum measured at 16 μJ/cm² of a laminate having a secondary diffraction grating structure formed on a perovskite film among the laminates produced in Example 1.

FIG. 8 is an AFM photograph showing a secondary diffraction grating structure of a perovskite film.

FIG. 9 shows ASE emission spectrum of a laminate produced in Example 2.

### DETAILED DESCRIPTION OF INVENTION

Hereafter, the present invention is described in detail. As provided below, the constituent elements may be described based on representative embodiments and specific examples of the present invention, but the present invention is not limited to such embodiments and specific examples. As used herein, a numerical range expressed using “to” means a range that includes the numerical values before and after “to” as the minimum and maximum values, respectively. As used herein, a “major constituent” refers to a constituent that accounts for the largest portion of the content of something. A hydrogen atom present in a compound molecule used in the present invention is not particularly limited in terms of isotopic species. For example, all hydrogen atoms in a molecule can be ¹H, or all or part of them can be ²H [heavy hydrogen (deuterium) D].

### Laminate Production Method

The laminate production method of the present invention is a method for producing a laminate of a resin film and a perovskite film, including a step of compressing a preliminary product having the resin film, the perovskite film and an inorganic support in that order with heating followed by separating the laminate of the resin film and the perovskite film from the inorganic support.

When a preliminary product having a resin film, a perovskite film and an inorganic support in that order is compressed with heating, the indented profile of the surface (transfer surface) on the perovskite film side of the inorganic support is precisely transferred onto the perovskite film and simultaneously the perovskite film is welded to the resin film to form a laminate of a resin film and a perovskite film. Subsequently, the laminate is separated from the inorganic support to give a laminate that has, on the surface of the perovskite film therein, an indented profile of a reverse pattern of the transfer surface.

In that manner, according to the laminate production method of the present invention, a perovskite film having an indented pattern formed on the surface thereof can be provided by merely compressing a preliminary product having a resin film, a perovskite film and an inorganic support with heating, the method of the present invention does not require any complicated step of photolithography in forming a perovskite film. In addition, the preliminary product can be produced merely by forming a perovskite film on an inorganic support and then laminating a resin film on the perovskite film, and therefore in the production method of the present invention, the resin can be prevented from being in contact with a solvent of the perovskite film-forming coating liquid, and the solvent for the coating liquid can be selected relatively freely. Consequently, according to the laminate production method of the present invention, a laminate having an indented pattern on the surface of a perovskite film can be produced in a simplified manner, therefore improving the production efficiency and reducing the production costs for various devices to which the laminate is applied.

In the following, the constitutions of the inorganic support, the perovskite film and the resin film for use in the laminate production method of the present invention, and the production steps for the laminate are described in detail.

### Inorganic Support

The inorganic support for use in the present invention can be a master grating for transferring the indented pattern thereof on a surface of a perovskite film. In this case, the inorganic support having, as formed on the surface (transfer surface) thereof, a reverse pattern to the indented profile to be formed on a perovskite film is used.

The indented pattern on the transfer surface of the inorganic support can be appropriately selected in accordance with the intended use of the laminate to be produced. For example, in the case where the laminate is for optical devices utilizing the diffraction grating structure of the perovskite film therein, an inorganic support (master grating) having, as formed thereon, a reverse pattern to the diffraction grating to be given to the perovskite is used. The diffraction grating to be formed on a perovskite film is specifically described in the section of <Laminate> to be given hereinunder. The height difference in the indented pattern of the inorganic support is preferably 30 to 70 nm. The optimized height difference will be a function of total film thickness and target lasing wavelength. A grating with a 70 nm height difference was used to demonstrate that transfer of high aspect ratio features is possible.

The constituent material for the inorganic support is, though not particularly limited thereto, preferably one which is excellent in processability and from which the perovskite film formed on the surface thereof can be readily peeled after heating compression. The constituent material for the inorganic support includes glass, metals and metal oxides, and is preferably a silicon thermal oxide film formed by thermal oxidation of a silicon substrate. One alone or two or more of these materials may be used either singly or as combined.

On the surface of the inorganic support formed of any of these materials, an indented profile can be formed, for example, through photolithography or etching. Here, the master grating once formed can be used repeatedly in laminate production. Consequently, even though photolithography is used in producing the inorganic support, there does not occur any problem of complicating the production process and increasing the production cost as in the case of using photolithography for forming a perovskite film.

Though not particularly limited thereto, the thickness of the inorganic support is preferably 0.1 to 2 mm.

### Perovskite Film

“Perovskite film” in the present invention is a film formed of a perovskite compound. “Perovskite compound” is an ionic compound composed of an organic cation or an inorganic cation, a divalent metal ion, and a halide ion, and can form a perovskite crystal structure. The perovskite compound for use in the present invention may be a three-dimensional perovskite in which the constituent ions form a perovskite structure to regularly align in three-dimensional directions, or may also be a two-dimensional perovskite in which a two-dimensionally aligned inorganic layer of an inorganic skeleton corresponding to the octahedral moiety of a perovskite structure and an organic layer of aligned organic cations are alternately layered to form a layered structure. The perovskite compound of the type includes compounds represented by the following general formulae (1) to (4). Among these, the compounds represented by the general formulae (1) to (3) are compounds capable of forming a two-dimensional perovskite structure, and the compound represented by the general formula (4) is a compound capable of forming a three-dimensional perovskite structure. The organic cation in the general formulae (1) to (4) may be substituted with an inorganic cation such as a cesium ion.

A₂BX₄ (1)

A²₂A¹ₙ₋₁BₙX₃ₙ₊₁ (2)

A²₂A¹ₘBₘX₃ₘ₊₂ (3)

A³BX₃ (4)

In the general formulae (1) to (4), A, A¹, A², and A³ each independently represent an organic cation, B represents a divalent metal ion, X represents a halide ion. However, in the formulae (2) and (3), A² is an organic cation having a larger carbon number than that of A¹.

In the general formula (1), two As and four Bs each may be the same as or different from each other.

In the general formulae (2) and (3), n and m each correspond to the lamination number of octahedrons in the inorganic layer, and are an integer of 1 to 100. In the general formulae (2) and (3), two A²s and plural Xs each may be the same as or different from each other. In the general formula (2), where n is 2 or more, plural Bs may be the same as or different from each other, and where n−1 is 2 or more, plural A¹s may be the same as or different from each other. In the general formula (3), where n is 2 or more, plural A¹s and plural Bs each may be the same as or different from each other.

The organic cation to be represented by A and A² is preferably an ammonium cation represented by the following general formula (5).

R₄N⁺ (5)

In the general formula (5), R represents a hydrogen atom or a substituent, and at least one of four Rs is a substituent having 2 or more carbon atoms. In the case where two or more of Rs each are a substituent, plural substituents may be the same as or different from each other. The substituent includes, not particularly limited thereto, an alkyl group, an aryl group and a heteroaryl group. These substituents each may be further substituted with an alkyl group, an aryl group, a heteroaryl group, a halogen and the like. Regarding the carbon number of the substituent having 2 or more carbon atoms, the carbon number of the alkyl group is preferably 2 to 30, more preferably 2 to 10, even more preferably 2 to 5. The carbon number of the aryl group is preferably 6 to 20, more preferably 6 to 18, even more preferably 8 to 10. The carbon number of the heteroaryl group is preferably 5 to 19, more preferably 5 to 17, even more preferably 7 to 9. The hetero atom that the heteroaryl group has includes a nitrogen atom, an oxygen atom and a sulfur atom.

The organic cation represented by A² in the general formula (3) is also preferably an organic cation represented by the following general formula (7).

(R¹²₂C═NR¹³₂)⁺ (7)

In the general formula (7), R¹² and R¹³ each independently represent a hydrogen atom or a substituent, R¹²s may be the same as or different from each other, and R¹³s may be the same as or different from each other. Not particularly limited, the substituent includes an alkyl group, an aryl group, an amino group and a halogen atom. Here, the alkyl group, the aryl group and the amino group each may be further substituted with an alkyl group, an aryl group, an amino group, a halogen atom or the like. Regarding the carbon number of the substituent, the carbon number of the alkyl group is preferably 1 to 30, more preferably 1 to 20, even more preferably 1 to 10. The carbon number of the aryl group is preferably 6 to 30, more preferably 6 to 20, even more preferably 6 to 10.

As the organic cation represented by A and A², formamidinium, cesium or the like is also employable in addition to ammonium.

The organic cation represented by A¹ and A³ is preferably an ammonium cation represented by the following general formula (6).

R¹¹₄N⁺ (6)

In the general formula (6), R¹¹ represents a hydrogen atom or a substituent, and at least one of four R¹¹s is a substituent. The number of the substituents of four R¹¹s is preferably 1 or 2, more preferably 1. Specifically, it is preferable that, among four R¹¹s constituting the ammonium cation, one is a substituent and the others are hydrogen atoms. In the case where two or more of R¹¹s are substituents, plural substituents may be the same as or different from each other. Not particularly limited, the substituent includes an alkyl group and an aryl group (phenyl group, naphthyl group, etc.). These substituents each may be further substituted with an alkyl group, an aryl group or the like. Regarding the carbon number of the substituent, the carbon number of the alkyl group is preferably 1 to 30, more preferably 1 to 20, even more preferably 1 to 10. The carbon number of the aryl group is preferably 6 to 30, more preferably 6 to 20, even more preferably 6 to 10.

As the organic cation represented by A¹ and A³, formamidinium, cesium or the like is also employable in addition to ammonium.

The divalent metal ion represented by B includes Cu²⁺, Ni²⁺, Mn²⁺, Fe²⁺, Co²⁺, Pd²⁺, Ge²⁺, Sn²⁺, Pb²⁺, and Eu²⁺.

The halide ion represented by X includes fluoride, chloride, bromide and iodide ions. The halide ions represented by three Xs all may be the same, or may also be a combination of two or three halide ions.

Specific preferred examples of the perovskite compound represented by the general formula (1) include: tin-based perovskites such as [CH₃(CH₂)ₙ₂NH₃)]₂SnI₄ (n2=2 to 17), (C₄H₉C₂H₄NH₃)₂SnI₄, (CH₃(CH₂)ₙ₃(CH₃)CHNH₃)₂SnI₄ [n3=5 to 8], (C₆H₅C₂H₄NH₃)₂SnI₄, (C₁₀H₇CH₂NH₃)₂SnI₄, and (C₆H₅C₂H₄NH₃)₂SnBr₄; and lead-based perovskites such as [CH₃(CH₂)ₙ₂NH₃)]₂PbI₄ (n2=2 to 17), (C₄H₉C₂H₄NH₃)₂PbI₄, (CH₃(CH₂)ₙ₃(CH₃)CHNH₃)₂PbI₄ [n3=5 to 8], (C₆H₅C₂H₄NH₃)₂PbI₄, (C₁₀H₇CH₂NH₃)₂PbI₄, and (C₆H₅C₂H₄NH₃)₂PbBr₄. However, perovskite compounds that may be used in the present invention are not limited to these compounds.

Specific preferred examples of the perovskite compounds represented by the general formula (2) include (C₄H₉NH₃)₂SnI₄, (C₄H₉NH₃)₂(CH₃NH₃)Sn₂I₇, (C₄H₉NH₃)₂(CH₃NH₃)₂Sn₃I₁₀, (C₄H₉NH₃)₂(CH₃NH₃)₃Sn₄I₁₃, (C₄H₉NH₃)₂(CH₃NH₃)₄Sn₅I₁₆, (CH₃(CH₂)ₙNH₃)₂PbI₄ (n=2 to 17), (C₄H₉C₂H₄NH₃)₂PbI₄, (CH₃(CH₂)ₙ(CH₃)CHNH₃)₂PbI₄ [n=5 to 8], (C₆H₅C₂H₄NH₃)₂PbI₄, (C₁₀H₇CH₂NH₃)₂PbI₄ and (C₆H₅C₂H₄NH₃)₂PbBr₄.

Specific preferred examples of the perovskite compound represented by the general formula (3) include: [NH₂C(I)=NH₂]₂(CH₃NH₃)₂Sn₂I₈, [NH₂C(I)=NH₂]₂(CH₃NH₃)₃Sn₃I₁₁, and [NH₂C(I)=NH₂]₂(CH₃NH₃)₄Sn₄I₁₄.

Specific preferred examples of the perovskite compound represented by the general formula (4) include: CH₃NH₃PbI₃, CH₃NH₃PbCl₃, CH₃NH₃PbBr₃, CH₃NH₃SnI₃, CH₃NH₃SnI_{q}F_{3-q}(wherein q represents an integer of 0 to 2), CH₃NH₃SnCl₃, CH₃NH₃SnBr₃, (NH₂)₂CHSnI₃, and CsSnCl₃. CH₃NH₃PbI₃, CH₃NH₃SnI_{q}F_{3-q}, and (NH₂)₂CHSnI₃ are preferred.

The perovskite compounds usable in the present invention are not limitatively interpreted by the compounds exemplified hereinabove. One alone or two or more kinds of perovskite compounds can be used either singly or as combined. Not particularly limited, the thickness of the perovskite film is generally 10 to 1000 nm or so.

### Resin Film

Not particularly limited, the constituent material for the resin film for use in the present invention is preferably a flexible resin material excellent in compatibility with the perovskite film, and is more preferably a thermoplastic resin. Preferred examples of the resin material include polyester resins such as polyethylene terephthalate (PET), polybutylene terephthalate, and polyethylene naphthalate; and fluororesins such as polytetrafluoroethylene (PTFE), and ethylene-tetrafluoroethylene copolymer. In addition, vinylic resins such as polyvinyl chloride and polyvinylidene chloride, polyolefin resins such as polyethylene and polypropylene, as well as ethylene-vinyl acetate copolymers, polycarbonates, polyamides, polyurethanes are also usable as materials for the resin film.

Not particularly limited, the thickness of the resin film is preferably 0.1 to 2 mm.

### Production Step for Laminate

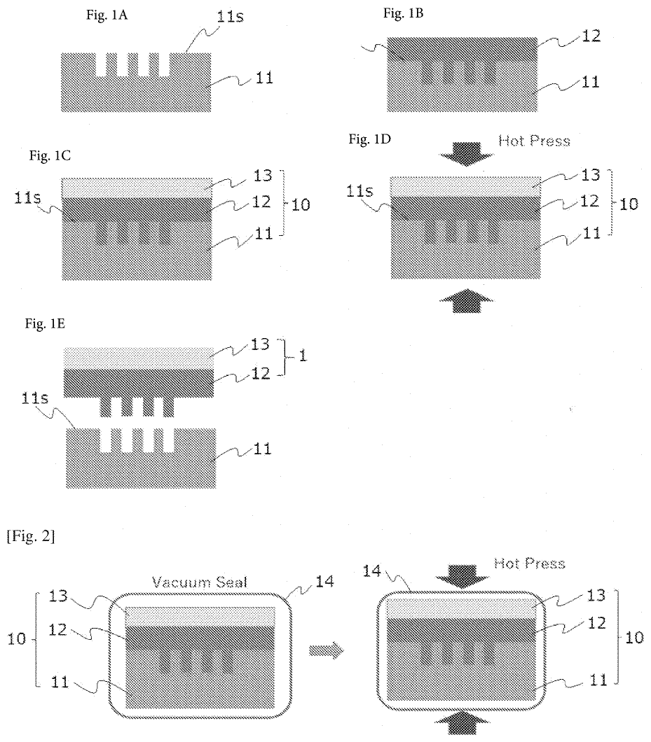

As described above, in the production step for a laminate of the present invention, a laminate is produced according to a step (laminate production step) of compressing a preliminary product having a resin film, a perovskite film and an inorganic support with heating followed by separating the laminate of a resin film and a perovskite film from the inorganic support. In the following, a step [1] for producing a preliminary production for use in the above step and a laminate production step [2] for producing an intended laminate from the preliminary product according to a predetermined process are described with reference to FIG. 1.

### [1] Preliminary Product Production Step

A preliminary product can be produced by forming a perovskite film on the surface of an inorganic support and the laminating a resin film on the perovskite film.

### (1-1) Perovskite Film Formation Step

For forming a preliminary product, first, as shown in FIG. 1a), an inorganic support 11 having an indented pattern on the transfer surface 11s thereof is prepared. Then, as shown in FIG. 1b), a perovskite film 12 is formed on the transfer surface 11s of the inorganic support 11.

A method for forming the perovskite film 12 is not particularly limited, and may be a wet process such as a solution coating method, or a dry process such as a vacuum evaporation method, but is preferably a solution coating method. According to a solution coating method, film formation can be attained using a simplified apparatus and within a short period of time, and the method is advantageous in that mass production is easy and the production cost can be reduced.

For forming a perovskite layer of a perovskite compound A³BX₃ according to a solution coating method, a compound A³X formed of an organic cation and a halide ion and a metal halide compound BX₂ are reacted in a solvent to synthesize a perovskite compound, and a coating liquid containing the perovskite compound (perovskite precursor solution) is applied onto the surface of an inorganic support and dried thereon to form a film. Also a film that contains a perovskite compound of any other general formula than the above can be formed according to the method by synthesizing a perovskite compound in a solvent, then applying a coating liquid containing the resultant perovskite compound onto the surface of an inorganic support and drying it thereon.

The method to apply the coating liquid is not particularly limited, and can be a known conventional process such as gravure coating, bar coating, printing, spray coating, spin coating, dip coating, or die coating, and is preferably spin coating because it can form a uniform coating layer of a relatively small thickness.

The solvent in the coating liquid is not particularly limited as long as it can dissolve the perovskite compound. Specifically, it can be an ester (methyl formate, ethyl formate, propyl formate, pentyl formate, methyl acetate, ethyl acetate, pentyl acetate, or the like), a ketone (γ-butyrolactone, N-methyl-2-pyrrolidone, acetone, dimethyl ketone, diisobutyl ketone, cyclopentanone, cyclohexanone, methyl cyclohexanone, or the like), an ether (diethyl ether, methyl-tert-butyl ether, diisopropyl ether, dimethoxymethane, dimethoxyethane, 1,4-dioxane, 1,3-dioxolan, 4-methyldioxolan, tetrahydrofuran, methyl tetrahydrofuran, anisole, phenetole, or the like), an alcohol (methanol, ethanol, 1-propanol, 2-propanol, 1-butanol, 2-butanol, tert-butanol, 1-pentanol, 2-methyl-2-butanol, methoxypropanol, diacetone alcohol, cyclohexanol, 2-fluoroethanol, 2,2,2-trifluoroethanol, 2,2,3,3-tetrafluoro-1-propanol, or the like), a glycol ether (cellosolve) (ethylene glycol monomethyl ether, ethylene glycol monoethyl ether, ethylene glycol monobutyl ether, ethylene glycol monoethyl ether acetate, triethylene glycol dimethyl ether, or the like), an amide solvent (N,N-dimethyl formamide, acetamide, N,N-dimethyl acetamide, or the like), a nitrile solvent (acetonitrile, isobutyronitrile, propionitrile, methoxyacetonitrile, or the like), a carbonate agent (ethylene carbonate, propylene carbonate, or the like), a halogenated hydrocarbon (methylene chloride, dichloromethane, chloroform, or the like), a hydrocarbon (n-pentane, cyclohexane, n-hexane, benzene, toluene, xylene, or the like), dimethyl sulfoxide, or the like. It can also have two or more of ester, ketone, ether, and alcohol functional groups (i.e., —O—, —CO—, —COO—, —OH), or it can be an ester, a ketone, an ether, or an alcohol in which a hydrogen atom in the hydrocarbon portion is replaced by a halogen atom (particularly a fluorine atom).

The amount of the perovskite compound contained in the coating liquid is preferably 1 to 50% by mass based on the entire coating liquid, more preferably 2 to 30% by mass, further preferably 5 to 20% by mass.

Also preferably, after the coating liquid is applied onto the surface of an inorganic support, the resultant coating film is heat-treated. Preferably, the heat treatment temperature for the coating film is 70 to 130° C.

Preferably, the drying of the coating liquid applied onto the surface of an inorganic support is spontaneous drying or drying under heat in an atmosphere purged with an inert gas such as nitrogen. The heat treatment may be also for drying the coating liquid. In addition, for example, for forming a perovskite layer of a perovskite compound A³BX₃ according to a vacuum evaporation method, a co-evaporation method of co-evaporating a compound A³X formed of an organic cation and a halide ion and a metal halide BX₂ from different evaporation sources can be employed. A film containing a perovskite compound of any other general formula than the above can also be formed through co-evaporation of a compound formed of an organic cation and a halide ion and a metal halide compound according to the above method.

### (1-2) Resin Film Lamination Step

Next, as shown in FIG. 1c), a resin film 13 is laminated on the surface opposite to the inorganic support 11 side of the formed perovskite film 12 to give a preliminary product 10. Specifically, a resin film formed like a sheet is layered on the perovskite film for lamination thereon. At this time, an adhesive may be applied onto at least one of the surface to be on the perovskite film side of the resin film, and the surface of the perovskite film on which the resin film is to be laminated, and then a resin film may be layered on the perovskite film, or an adhesive layer (adhesive sheet) may be put between the resin film and the perovskite film. In that manner, even when the affinity between the resin film and the perovskite film is relatively low, a laminate of the two films integrated together can be provided with ease. If desired, the resin film may be formed by applying a solution of a resin material or a hot-melt liquid of a resin material onto a perovskite film followed by solidifying the solution or the liquid thereon. For specific examples of a coating method with a solution or a hot-melt liquid of a resin solution, reference may be made to specific examples of a coating method with a coating liquid for perovskite film formation (perovskite precursor solution) given hereinabove.

### [2] Laminate Production Step

In this step, as shown in FIG. 1d), the prepared preliminary product 10 is compressed with heating, and then, as shown in FIG. 1e), a laminate 1 of the resin film 13 and the perovskite film 12 is separated from the inorganic support 11.

When the preliminary product 10 is compressed with heating, the perovskite film is pressed against the transfer surface 11s of the inorganic support 11, and the indented profile of the transfer surface 11s is precisely transferred onto the surface of the perovskite film and simultaneously the perovskite film 12 is bonded to the resin film 13 to form a laminate 1 of the resin film 13 and the perovskite film 12. Subsequently, the laminate 1 is separated from the inorganic support 11 to give an intended laminate 1 where the indented profile of the transfer surface 11s of the inorganic support 11 has been transferred onto the surface of the perovskite film.

Here, the bonding between the resin film and the perovskite film in this step is preferably welding. “Welding” means penetration of a hot-melted resin into the surface of a perovskite film on the molecular level to be in a welded state after cooling solidification. Welding of a resin film to a perovskite film can be confirmed through electronic microscopy of the cross section of the laminate of the films.

Also as shown in FIG. 2, compression of the preliminary product 10 with heating is preferably attained after the preliminary product 10 is put into a bag 14 and sealed up therein, and is more preferably carried out after the bag is degassed to be in vacuum. Also preferably, the compression of the preliminary product 10 sealed up in the bag is carried out under hydraulic pressure, and is preferably carried out according to a hot isotactic pressing method. Accordingly, the preliminary product is isotropically pressed and the indented profile on the transfer surface of the inorganic support can be more precisely transferred onto the surface of the perovskite film. Here, the pressure medium for compression may be a liquid such as water, or may also be an inert gas such as argon or nitrogen.

The pressure in pressing the preliminary product is preferably 10 MPa or more, more preferably 20 MPa or more, even more preferably 40 MPa or more, and still more preferably 100 MPa or more.

The temperature in compression of the preliminary product is preferably not lower than the glass transition temperature Tg of the resin constituting the resin film and is lower than the melting point thereof, and is also preferably 40° C. or higher and lower than the glass transition temperature of the resin constituting the resin film. The glass transition temperature of the resin can be measured through DSC.

### Laminate

Next, the laminate of the present invention is described.

The laminate of the present invention is a laminate of a resin film and a perovskite film, in which the resin film is welded to the perovskite film.

For the description and the preferred range, and specific examples of the “resin film” and the “perovskite film” in the laminate of the present invention as well as the description of “welding”, reference may be made to the corresponding description in the section of <Laminate Production Method> given hereinabove.

Preferably, the perovskite film in the laminate of the present invention has a diffraction grating on the surface on the side opposite to the resin film side. Not particularly limited, the pattern of the diffraction grating that the perovskite film has may be a one-dimensional diffraction grating formed of a large number of linear grooves aligning in parallel, or may be a two-dimensional diffraction grating where linear grooves or dotted projections or recessions align in a two-dimensional direction. Specific patterns of the two-dimensional diffraction grating include a matrix pattern where a large number of linear grooves extending in an X-direction and a large number of linear grooves extending in a Y-direction align alternately with each other, and a matrix pattern where a large number of projection-recession lines of a large number of projections or recessions aligning in an X-direction, and a large number of projection-recession lines of a large number of projections or recessions aligning in a Y-direction align alternately to each other. The diffraction grating pattern may also be a circular pattern consisting of grooves which are concentrically or spirally formed, or a large number of projections or recessions aligning concentrically or spirally, and any pattern capable of forming diffraction rays can be employed here with no limitation.

The laminate of the present invention is preferably used for light emitting devices such as laser devices. Also in particular, the laminate having a diffraction grating on the surface opposite to the resin film side of the perovskite film can be favorably used for optical devices for dividing a light of various wavelengths in mixture into individual wavelength light fractions, or for distributed-feedback laser devices where the perovskite film functions as an active layer and an optical resonator.

### Light-Emitting Device

Next, the light-emitting device of the present invention is described.

The light-emitting device of the present invention includes the laminate of the present invention.

For the description of the “laminate” of the present invention, reference may be made to the description in the column of <Laminate> given hereinabove.

Preferably, a major part (more than 50%) of the light emitted by the light-emitting device of the present invention is a light derived from the perovskite film.

The light-emitting device of the present invention may be an organic photoluminescent device that emits the light from photoexcitation of the perovskite film, directly outside the device, or may be an organic electroluminescent device that emits the light from current excitation of the perovskite film, directly outside the device, or may also be a laser device that amplifies the light from the perovskite film through photoexcitation or current excitation thereof to emit the thus-amplified light as a laser light. Here, the laminate of the present invention can form a fine indented pattern like a diffraction grating, precisely on the surface of the perovskite film therein, and can be produced in a simplified process. Consequently, the light-emitting device of the present invention can be favorably constructed as a distributed-feedback laser device where the perovskite film of the laminate functions as an active layer and an optical resonator, and therefore according to the present invention, there can be provide an inexpensive distributed-feedback laser device.

The light-emitting device of the present invention may be formed of the laminate of the present invention alone, or may have any one or more organic layers in addition to the laminate. In the case where the light-emitting device is a current excitation-type device, preferably, the device has a pair of electrodes (anode and cathode) for introducing a current into the perovskite film therein. Such a current excitation-type light-emitting device may have one or more organic layers between the laminate and each electrode. The organic layers include a hole transport layer, a hole injection layer, an electron blocking layer, a hole blocking layer, an electron injection layer, an electron transport layer, and an exciton blocking layer. The hole transport layer may be a hole injection/transport layer having a hole injection function, and the electron transport layer may be an electron injection/transport layer having an electron injection function. As the materials for each organic layer and each electrode, any known materials generally used for organic electroluminescent devices can be used.

### EXAMPLES

Hereafter, with reference to Examples and Comparative Examples, features of the present invention are more specifically described. Materials, details of processes, process steps, and the like as shown below can be changed as appropriate without departing from the spirit of the present invention. Accordingly, the scope of the present invention should not be construed as limited by specific examples as shown below.

### Measurement Methods

ASE (Amplified Spontaneous Emission) and laser measurements, and atomic force microscopy of perovskite films were carried out under the conditions mentioned below.

### (1) Amplified Spontaneous Emission and Laser Measurements

During ASE measurements films were pumped with a nitrogen laser normal to the substrate surface (337 nm, 10 Hz, 0.8 nanosecond, Usho Optical Systems, KEN-2020). The excitation light was focused using a cylindrical lens to form a stripe with an area around 4000×300 μm. Spectra were measured from the edge emission of a cleaved film. For measurements of DFB lasers, the substrate was rotated to around 20° and the PL was measured normal to the surface. The length of the stripe was reduced to less than 2 mm to fit within the grating structure. The light was passed through a long pass filter to remove the excitation light and then was focused with a convergent lens onto a fiber optic cable of a photonic multichannel analyzer (Hamamatsu PMA 12-C10027). The energy of the pulse was measured with a micro-joule meter and the area of the spot measured by a CCD camera. Films were measured in air without encapsulation, and appeared to be stable for the duration of the measurements.

### (2) Atomic Force Microscopy

AFM images were measured in ambient air using a JEOL JSPM-5400 microscope and an AC mode cantilever (budget sensors).

### Production of Laminate for Distributed-Feedback Laser Device

### Example 1 Production Example for laminate using PET film as resin film, using CH₃NH₃PbI₃ as perovskite film, and using silicon thermal oxide film as inorganic support (master grating substrate)

In this Example, a laminate having a one-dimensional diffraction grating or a two-dimensional diffraction grating on a perovskite film was produced.

### (1) Master Grating Substrate Fabrication

Master gratings were patterned on thermally grown SiO₂ wafers by e-beam lithography. Clean substrates were boiled in IPA prior to coating with e-beam resist. The resist was made by first coating the substrate with o-aminophenol (OAP), 4000 rpm, and annealed at 120° C. for 2 min. This was followed by a mixture of resist (ZEP520A-7:ZEP-A, 1:2) that was spun at 2000 rpm, and annealed for 180° C. for 4 min. Lastly a layer of e-spacer 300Z was spun at 2000 rpm and annealed at 80° C. for 4 min. Films were patterned in a JEOL e-beam lithography system with 100 μC/cm². Patterned films were developed in ZED-N50 for around 90 sec, and promptly rinsed in IPA. Gratings were etched to a depth of around 70 nm using a reactive ion etch, with a forward power around 50 W, and a gas mixture of fluoroform (CHF₃, partial pressure around 20 Pa) and oxygen (partial pressure around 5 Pa). The resist was stripped with chloroform and the substrate subsequently cleaned with oxygen plasma.

### (2) Perovskite Film Fabrication and Resin Film Stack (Preliminary Product Fabrication)

Perovskite films were prepared using a stoichiometric solution of methylammonium iodide and lead iodide at a solution concentrations of 0.6M, in DMF (dimethylformamide) with 0.6M of DMSO (dimethyl sulfoxide). The film was spin cast in a dry nitrogen environment at 500 rpm for 10 sec followed by 5000 rpm, where diethyl ether was dropped onto the film at 5 sec. Films were annealed at 100° C. for 20 min.

The perovskite film was placed in contact with a 1 mm thick PET (polyethylene terephthalate) film (Tg: 69° C.) to form a preliminary product consisting of the PET film, the perovskite film, and the master grating substrate.

### (3) Transfer by Isostatic Press (Formation of Laminate consisting of PET Film and Perovskite Film)

The preliminary product was loaded into a vacuum seal bag. The sealed bag was loaded into a heated chamber (90° C.) filled with water, and then the pressure was increased with a hydraulic press (50 MPa). The bag kept at elevated temperature and pressure for 10 min. Higher temperature pressing was more effective for film transfer than room temperature pressing. The transfer process was not particularly sensitive to exact pressure used, as lower pressures 20 MPa also worked.

### (4) Separation of Laminate from Master Grating Substrate

The laminate of the PET film and the perovskite film separated from the master grating substrate. The delamination of the perovskite film from the SiO₂ master grating appeared to be complete and reproducible.

### Example 2 Production Example for Laminate using PTFE Film as Resin Film, using CH3NH3PbI3 as Perovskite Film, and using Silicon Thermal Oxide Film as Inorganic Support

A laminate was produced in the same manner as in Example 1 except that a PTFE (polytetrafluoroethylene) film (Tg: 115° C.) was used instead of the PET film.

### Laminate Evaluation

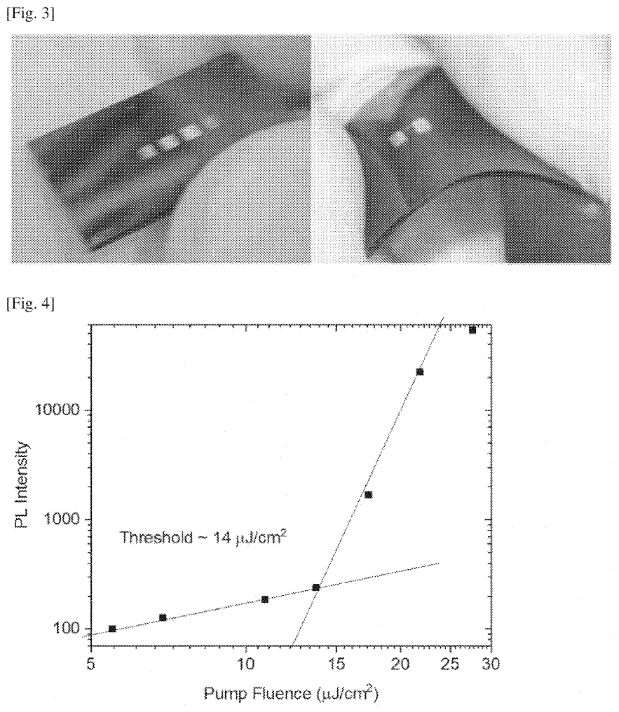

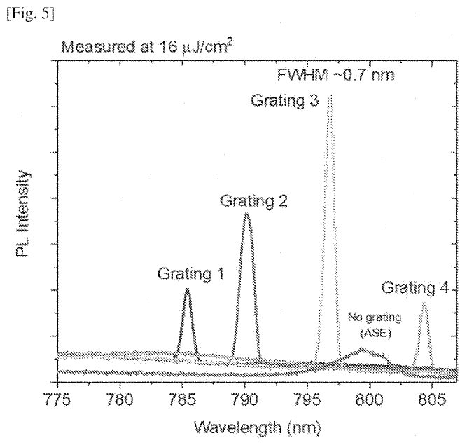

FIG. 3 shows a photograph a perovskite film transferred (welded) to a PET film in Example 1. In the photograph the diffraction pattern from the transferred grating film (perovskite film) is apparent. This transferred film was excited using a nitrogen laser and all transferred gratings demonstrated lasing, with a threshold of around 14 μ/cm² and PL characteristic of the grating pitch (FIGS. 4 and 5). The full width at half maximum (FWHM) of the laser emission was around 0.7 nm. The transferred film had appeared to have comparable properties to the original laser, so the film quality did not appear to undergo any meaningful change during transfer.

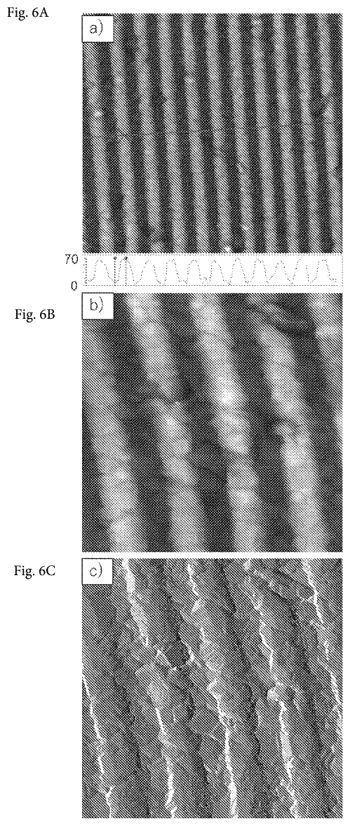

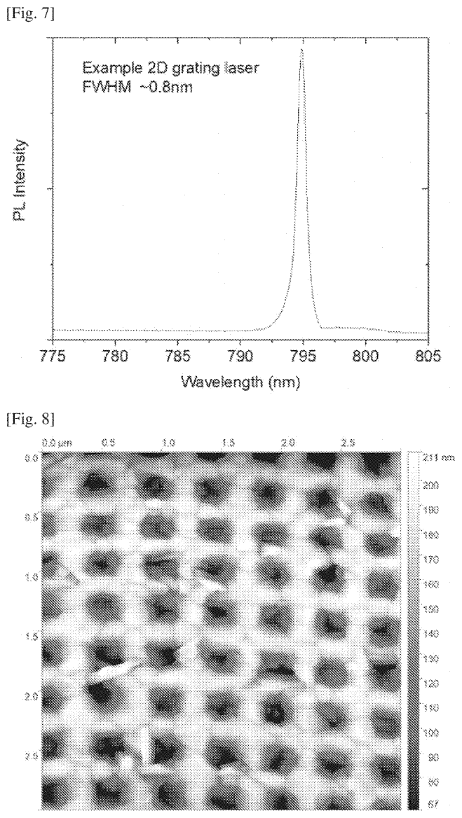

Closer inspection of the transferred film (perovskite film) with atomic force microscopy (AFM, FIG. 6), revealed a well-defined grating pattern with an aspect ratio comparable to the master grating (depth around 70 nm). One interesting feature of this process is that allows us to clearly observe the “underside” of the cast perovskite film. Higher resolution AFM images reveal the polycrystalline nature of the perovskite and how it conforms to the grating template (FIG. 6b)). The amplitude image highlights the step edges and makes the crystalline features easier to see (FIG. 6c)). Considering that the aspect ratio of the grating is approximately the same as the master we can assume that the film morphology has not changed significantly after film separation. We can then assume that the film surface observed is similar to the original annealed film. This could potentially give insights into how the perovskite film nucleates, and reveal any differences between the top and bottom surface. The transfer process appeared to work with arbitrary patterns, and to demonstrate this a 2D grating was used for this transfer process. This transferred film with a 2D grating also worked as a laser (FIGS. 7 and 8).

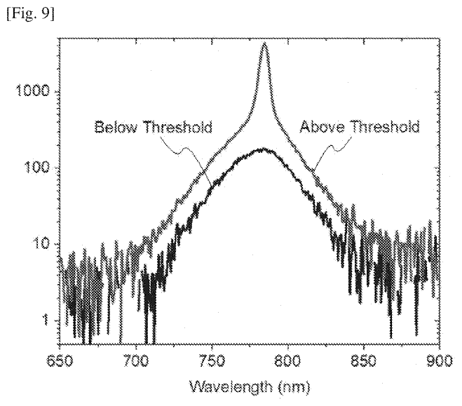

Furthermore, in Example 2 a perovskite film nearly completely transferred (welded) to PTFE and seemed to keep its original grating structure. The transferred film showed ASE emission (FIG. 9).

The above result showed that a perovskite film was transferred to a resin film by hot isostatic pressing. This process was shown viable for the replication of distributed-feedback gratings of arbitrary shape. The perovskite DFB lasers showed performance comparable to original film, and allows for the use of low cost flexible polymer substrates. This provides the significant advantages of being able to reuse gratings, and the ability to deposit perovskite films onto substrates that may otherwise dissolve in solvents.

### Industrial Applicability

According to the present invention, a perovskite film having, on the surface thereof, a fine indented pattern such as a diffraction grating structure can be provided as a laminate with a resin film, in a simplified process. The laminate can be used for light-emitting devices such as laser devices, and with that, inexpensive light-emitting devices can be provided. Consequently, the industrial applicability of the present invention is great.

### Reference Signs List

1 Laminate

10 Preliminary Product

11 Inorganic Support

11s Transfer Surface

12 Perovskite Film

13 Resin Film

14 Bag

1. A method for producing a laminate of a resin film and a perovskite film, comprising:
compressing a preliminary product having a resin film, a perovskite film and an inorganic support in that order with heating,
followed by separating the laminate of a resin film and a perovskite film from the inorganic support.

2. The method for producing a laminate according to claim 1, wherein the preliminary product is sealed in a bag and then compressed with heating.

3. (canceled)

4. The method for producing a laminate according to claim 1, wherein the preliminary product is pressed under 100 MPa or more.

5. The method for producing a laminate according to claim 1, wherein the heating is up to a temperature not lower than the glass transition temperature of the resin constituting the resin film and lower than the melting point thereof.

6. The method for producing a laminate according to claim 1, wherein the heating is up to a temperature not lower than 40° C. and lower than the glass transition temperature of the resin constituting the resin film.

7. The method for producing a laminate according to claim 1, wherein the inorganic support is a master grating and the perovskite film has a grating.

8. (canceled)

9. The method for producing a laminate according to claim 1, wherein the resin film is a thermoplastic resin film.

10-12. (canceled)

13. A laminate of a resin film and a perovskite film, wherein the resin film is welded to the perovskite film and the perovskite film has a grating on the surface opposite to the resin film side.

14. (canceled)

15. The laminate according to claim 13, wherein the perovskite film contains a perovskite compound represented by the following general formula (4):
A₃BX₃ (4)
wherein A³ represents an organic cation, B represents a divalent metal ion, X represents a halide ion, and three Xs may be the same as or different from each other.

16. The laminate according to claim 13, wherein the resin film is flexible.

17-20. (canceled)

21. The laminate according to claim 13 for light-emitting devices.

22. The laminate according to claim 13 for laser devices.

23. A light-emitting device having the laminate of claim 13.

24. A laser device having the laminate of claim 13.

25. (canceled)
